(19) United States
(12) Patent Application Publication
(10) Pub. No.: US 2025/0046634 A1
(43) Pub. Date: Feb. 6, 2025

(54) APPARATUS AND METHOD FOR MANUFACTURING DISPLAY DEVICE

(71) Applicant: Samsung Display Co., Ltd., Yongin-Si (KR)

(72) Inventors: Soonjong Park, Yongin-si (KR); Junhee Han, Yongin-si (KR)

(21) Appl. No.: 18/583,875

(22) Filed: Feb. 22, 2024

(30) Foreign Application Priority Data
Aug. 1, 2023 (KR) 10-2023-0100704

(51) Int. Cl. H01L 21/67

(52) U.S. Cl. CPC H01L 21/67253; H01L 21/67115; H01L 21/67207; H01L 21/67248

(57) ABSTRACT

There is provided an apparatus for manufacturing a display device, the apparatus including a processor including a first process line including a plurality of first process devices configured to perform a first process, and a second process line including a plurality of second process devices configured to perform a second process, and a controller configured to control the processor.

### CROSS-REFERENCE TO RELATED APPLICATION

This application is based on and claims priority, under 35 U.S.C. § 119, to Korean Patent Application No. 10-2023-0100704 filed on Aug. 1, 2023, in the Korean Intellectual Property Office, the disclosure of which is incorporated by reference herein in its entirety.

### BACKGROUND

### 1. Field

One or more embodiments relate to an apparatus and method, and more particularly, to an apparatus for and a method of manufacturing a display device.

### 2. Description of the Related Art

Mobility-based electronic devices are widely used. Mobile electronic devices that have been recently widely used include small electronic devices such as mobile phones as well as tablet personal computers (PCs).

In order to support various functions, mobile electronic devices include a display device for providing visual information such as an image to a user. Recently, as other components for driving display devices have been miniaturized, the proportion occupied by display devices in electronic devices is increasing. Also, structures that can be bent from a flat state to form an angled surface have been developed.

### SUMMARY

One or more embodiments include an apparatus for and method of manufacturing a display device capable of saving electricity and reducing depreciation without interfering with process performance.

Embodiments set forth herein are examples, and the scope of the disclosure is not limited thereby.

Additional aspects will be set forth in part in the description which follows and, in part, will be apparent from the description, or may be learned by practice of the presented embodiments of the disclosure.

According to one or more embodiments, an apparatus for manufacturing a display device includes a processor including a first process line including a plurality of first process devices for performing a first process, and a second process line including a plurality of second process devices for performing a second process, and a controller configured to control the processor, wherein each of the plurality of first process devices and the plurality of second process devices operates in a power saving mode, and the controller includes a management unit configured to generate an input variable including the target number of products to be processed during a predefined time duration in the first process line, the target number of products to be processed during the predefined time duration in the second process line, the number of the plurality of first process devices, the number of the plurality of second process devices, a processing speed of the plurality of first process devices, and a processing speed of the plurality of second process devices, a scheduler configured to receive the input variable from the management unit and output an output variable to the management unit, and a tool control (TC) unit configured to receive the output variable from the management unit and control the processor according to the output variable, wherein the output variable includes information about a power saving process device operating in a power saving mode among the plurality of first process devices and the plurality of second process devices, a power saving start time of the power saving process device, and a power saving end time of the power saving process device.

In each of the plurality of first process devices and the plurality of second process devices, a degree of power saving in the power saving mode may be adjusted to a plurality of levels, and the output variable may further include a degree of power saving of the power saving process device.

At least one of the plurality of first process devices and the plurality of second process devices may include a heat treatment device for heat-treating the products, wherein the heat treatment device may include a chamber, a heater disposed inside the chamber to emit heat, a temperature sensor configured to detect temperature inside the chamber, and a temperature controller configured to control a degree to which the heater emits heat based on information detected by the temperature sensor, wherein the TC unit may adjust the degree of power saving by controlling the temperature controller.

At least one of the plurality of first process devices and the plurality of second process devices may include a laser process device, wherein the laser process device may include a laser irradiation unit configured to irradiate a laser, a power sensor configured to detect power of the laser, and a power controller configured to control a degree of the power of the laser irradiated by the laser irradiation unit based on the information detected by the power sensor, wherein the TC unit may adjust the degree of power saving by controlling the power controller.

The management unit may generate an inquiry signal about a current power saving state of the processor.

The TC unit may transmit the inquiry signal to the processor, the processor may determine, upon receiving the inquiry signal, an inquiry variable including the number of products processed to date in the first process line and the number of products processed to date in the second process line, the TC unit may transmit the inquiry variable to the management unit, and the management unit may compare the inquiry variable, the input variable, and the output variable with each other to determine whether there is an error in an operation of the processor.

When the management unit determines that an error occurred in the operation of the processor, the management unit may input the inquiry variable and the input variable to the scheduler, and the scheduler may receive the inquiry variable and the input variable, modify the output variable, and output the modified output variable to the management unit.

The TC unit may receive the modified output variable from the management unit and control the processor according to the modified output variable.

The management unit may generate the inquiry signal multiple times at regular time intervals.

The plurality of second process devices may each perform the second process on the product on which the first process has been performed, and the first process may be different from the second process.

According to one or more embodiments, a method of manufacturing a display device includes performing, by a processor, a process, the processor including a first process line including a plurality of first process devices for performing a first process and a second process line including a plurality of second process devices for performing a second process, generating, by a management unit, an input variable including the target number of products to be processed during a predefined time in the first process line, the target number of products to be processed during the predefined time in the second process line, the number of the plurality of first process devices, the number of the plurality of second process devices, a processing speed of the plurality of first process devices, and a processing speed of the plurality of second process devices, inputting, by the management unit, the input variable to a scheduler, outputting, by the scheduler, an output variable to the management unit based on the input variable, and receiving, by a tool control (TC) unit, the output variable from the management unit to control the processor according to the output variable, wherein the output variable includes information about a power saving process device operating in a power saving mode from among the plurality of first process devices and the plurality of second process devices, a power saving start time of the power saving process device, and a power saving end time of the power saving process device.

The method may further include, in each of the plurality of first process devices and the plurality of second process devices, adjusting a degree of power saving in the power saving mode to a selected level of a plurality of levels, and including the selected level in the output variable.

The method may further include heat treating the products with a heat treatment device, wherein the heat treating may include placing the products in a chamber, applying heat with a heater disposed inside the chamber, detecting a temperature inside the chamber, controlling a degree to which the heater emits heat based on the temperature inside the chamber, and adjusting the degree of power saving by controlling the temperature.

The method may further include laser treating the products with a laser process device in at least one of the plurality of first process devices and the plurality of second process devices, wherein the laser treating may include irradiating the products with a laser beam, detecting a power level of the laser, controlling a power level of the laser based on the power that is detected, and adjusting the degree of power saving by controlling the power level.

The method may further include generating, by the management unit, an inquiry signal about a current power saving state of the processor.

The method may further include determining, by the processor upon receiving the inquiry signal, an inquiry variable including the number of products processed to date in the first process line and the number of products processed to date in the second process line, transmitting, by the TC unit, the inquiry variable to the management unit, and comparing, by the management unit, the inquiry variable, the input variable, and the output variable with each other to determine whether an error occurred in an operation of the processor.

The method may further include, upon determining that an error occurred in the operation of the processor using the inquiry variable and the input variable to modify the output variable and generate a modified output variable.

The method may further include controlling the processor according to the modified output variable.

The method may further include generating the inquiry signal multiple times at regular time intervals.

The method may further include performing, via the plurality of second process devices, the second process on the product on which the first process has been performed, wherein the first process may be different from the second process.

Various aspects, features, and advantages not explicitly described above will be apparent from a detailed description, the claims, and the drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic block diagram of an apparatus for manufacturing a display device, according to an embodiment;

FIG. 2 is a schematic plan view of a processor according to an embodiment;

FIG. 3 is a schematic flowchart of a method of manufacturing a display device, according to an embodiment;

FIG. 4 is a schematic block diagram of a heat treatment device according to an embodiment;

FIG. 5 is a schematic block diagram of a laser process device according to an embodiment;

FIG. 6 is a plan view schematically illustrating a display device according to an embodiment;

FIG. 7 is a cross-sectional view schematically illustrating a display device according to an embodiment; and

FIG. 8 is an equivalent circuit diagram of a pixel of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

The disclosure is subject to various modifications and may have many embodiments, certain of which are illustrated in the drawings and further described in the detailed description. The effects and features of the disclosure, and methods of achieving them will become clear with reference to the embodiments described below in detail together with the drawings. However, the disclosure is not limited to the embodiments described herein and may be implemented in various forms.

Hereinafter, embodiments will be described in detail with reference to the accompanying drawings, and when describing with reference to the drawings, the same or corresponding components are given the same reference numerals, and duplicate descriptions thereof will be omitted.

In the following embodiments, the terms first, second, etc. are not intended to be limiting, and are used to distinguish one component from another.

In the following embodiments, the singular expression includes the possibility of plural unless the context clearly indicates otherwise.

In the following embodiments, the terms “including” or “that has,” etc. are intended to imply the presence of the recited features or components and do not preclude the possibility of the addition of one or more other features or components.

In the following embodiments, when a portion of a film, area, component, etc. is to be over or on top of another portion, this includes not only when it is directly on top of another portion, however also when there are other films, areas, components, etc. arranged therebetween.

In the drawings, components may be exaggerated or reduced in size for ease of illustration. For example, the size and thickness of each configuration shown in the drawings are arbitrary for purposes of illustration and the disclosure is not necessarily limited to those shown.

In the following embodiments, the terms x-axis, y-axis, and z-axis are not limited to describing three orthogonal axes, and may be interpreted in a broad sense to include three axes in a Cartesian coordinate system. For example, the x-axis, y-axis, and z-axis may may also refer to different directions that are not orthogonal to one another.

In some embodiments, a particular sequence of processes may be performed in a different order than that described. For example, two processes described in succession may be performed substantially simultaneously, or may be performed in the opposite order from the order described.

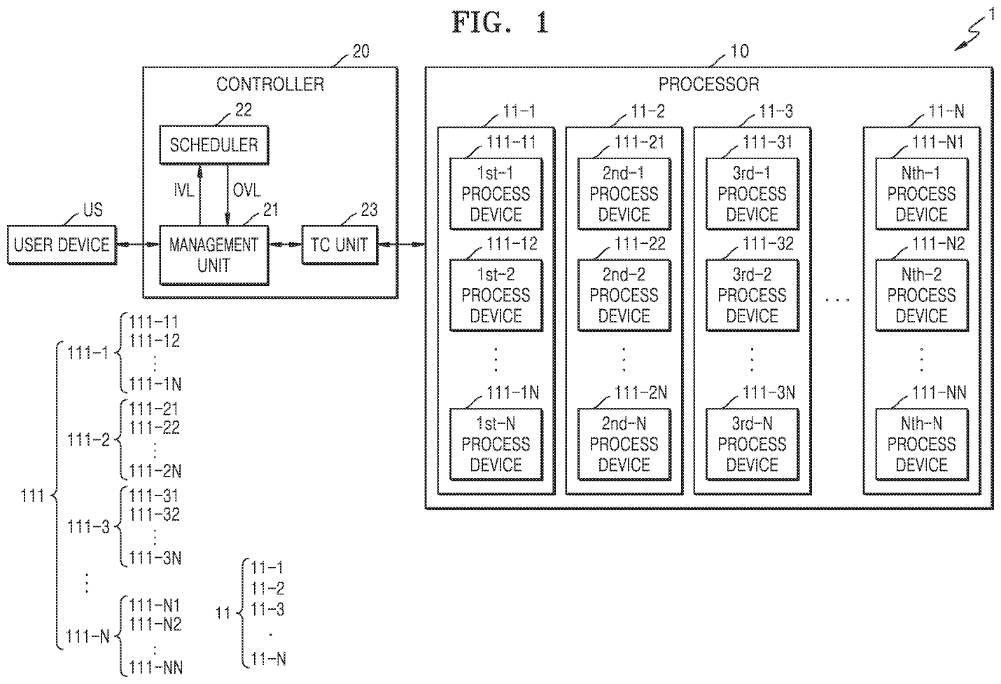

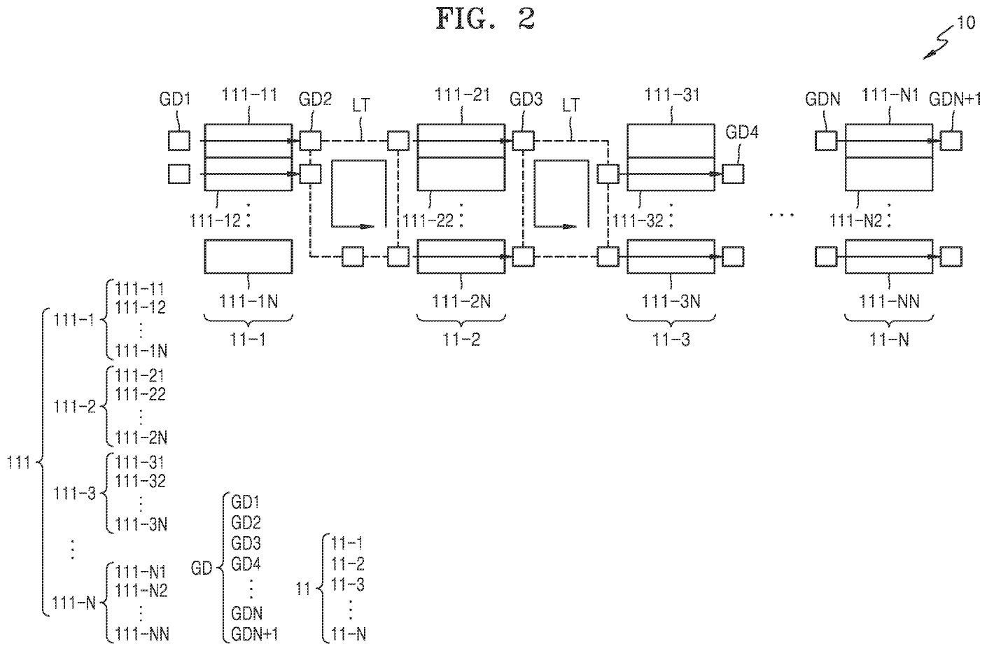

FIG. 1 is a schematic block diagram of an apparatus 1 (hereinafter, referred to as a display device manufacturing apparatus) for manufacturing a display device, according to an embodiment, and FIG. 2 is a schematic plan view of a processor according to an embodiment.

Referring to FIGS. 1 and 2, the display device manufacturing apparatus 1 may include a processor 10 and a controller 20.

The processor 10 may perform a process on a product GD. The processor 10 may include a plurality of process lines 11, and the plurality of process lines 11 may each include a plurality of process devices 111. The plurality of process devices 111 included in one process line 11 may perform the same process. Among the plurality of process lines 11, two or more process lines 11 may perform different processes. For example, the plurality of process lines 11 may perform different processes. In this case, the product GD may be processed while sequentially passing through the plurality of process lines 11.

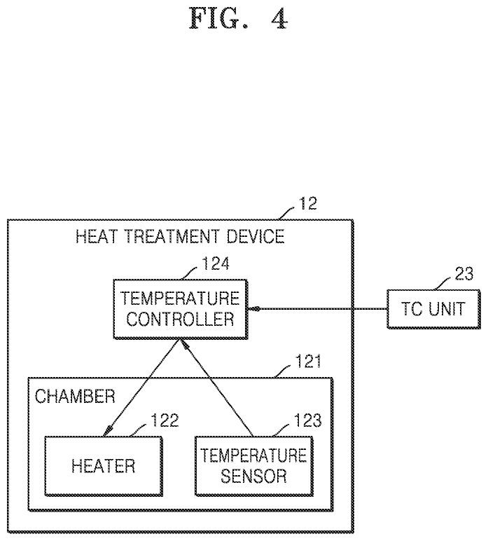

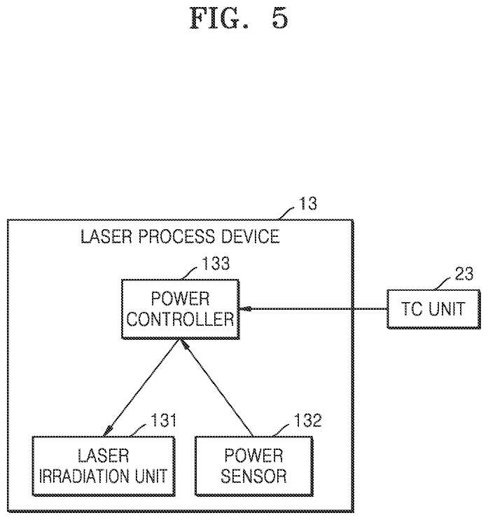

At least one of the plurality of process devices 111 may include a heat treatment device 12 (see FIG. 4). For example, at least one of the plurality of process devices 111 may include a deposition device for depositing a deposition material on the product GD. At least one of the plurality of process devices 111 may include a laser process device 13 (see FIG. 5). For example, at least one of the plurality of process devices 111 may include at least one of an exposure device that performs an extreme ultraviolet (EUV) process and a laser device that performs an excimer laser annealing (ELA) process.

For example, the plurality of process lines 11 may include a first process line 11-1 including a plurality of first process devices 111-1, a second process line 11-2 including a plurality of second process devices 111-2, a third process line 11-3 including a plurality of third process devices 111-3, . . . , and an Nth process line 11-N including a plurality of Nth process devices 111-N.

Also, for example, the plurality of first process devices 111-1 may include a 1st-1 process device 111-11, a 1st-2 process device 111-12, . . . , and a 1st-N process device 111-1N, and the plurality of second process devices 111-2 may include a 2nd−1 process device 111-21, a 2nd-2 process device 111-22, . . . , and a 2nd-N process device 111-2N. In addition, the plurality of third process devices 111-3 may include a 3rd-1 process device 111-31, a 3rd-2 process device 111-32, . . . , and a 3rd-N process device 111-3N, and the plurality of Nth process devices 111-N may include an Nth−1 process device 111-N1, an Nth-2 process device 111-N2, . . . , and an Nth-N process device 111-NN.

The first process line 11-1 may perform a first process, the second process line 11-2 may perform a second process, the third process line 11-3 may perform a third process, . . . , and the Nth process line 11-N may perform an Nth process. That is, the plurality of first process devices 111-1 may perform the first process, the plurality of second process devices 111-2 may perform the second process, the plurality of third process devices 111-3 may perform the third process, . . . , and the plurality of Nth process devices 111-N may perform the Nth process. The first process, the second process, the third process, . . . , and the Nth process may be different processes.

As depicted in FIG. 2, the product GD may be processed while sequentially moving through the first process line 11-1, the second process line 11-2, the third process line 11-3, . . . , and the Nth process line 11-N. For example, the product GD may be moved between the plurality of process lines 11 by a transfer robot (not shown). The plurality of second process devices 111-2 may perform the second process on the product GD on which the first process has been performed, the plurality of third process devices 111-3 may perform the third process on the product GD on which the second process has been performed, . . . , and the plurality of Nth process devices 111-N may perform the Nth process on the product GD on which an (N−1)th process has been performed.

A first product GD1 supplied through a first supply line may be processed into a second product GD2 as the first process is performed. The second product GD2 may be supplied to a second supply line along a movement path LT between the first supply line and the second supply line. The second product GD2 supplied through the second supply line may be processed into a third product GD3 as the second process is performed. The third product GD3 may be supplied to the third process line 11-3 along a movement path LT between the second supply line and the third process line 11-3. The third product GD3 supplied to the third process line 11-3 may be processed into a fourth product GD4 as the third process is performed. An Nth product GDN supplied to an Nth supply line may be processed into an (N+1)th product GDN+1 as the Nth process is performed. The (N+1)th product GDN+1 may be a final finished product manufactured by the display device manufacturing apparatus 1.

For example, the first product GD1 may be processed into the second product GD2 by the first process in the 1st-1 process device 111-11, and the second product GD2 may be processed into the third product GD3 by the second process in the 2nd-2 process device 111-22. In addition, the third product GD3 may be processed into the fourth product GD4 by the third process in the 3rd-1 process device 111-31, and finally the Nth product GDN may be processed into the (N+1)th product GDN+1 by the Nth process in the Nth-N process device 111-NN.

In FIG. 2, a case where a plurality of process devices 111 are arranged in a line in one process line 11 is shown. However, the case is just an example and the arrangement of the plurality of process devices 111 is not limited thereto. In addition, a case where the product GD moves counterclockwise along a square movement path LT between the plurality of process lines 11 is shown in FIG. 2. However, this case is also just an example and the movement path LT of the product GD is not limited thereto.

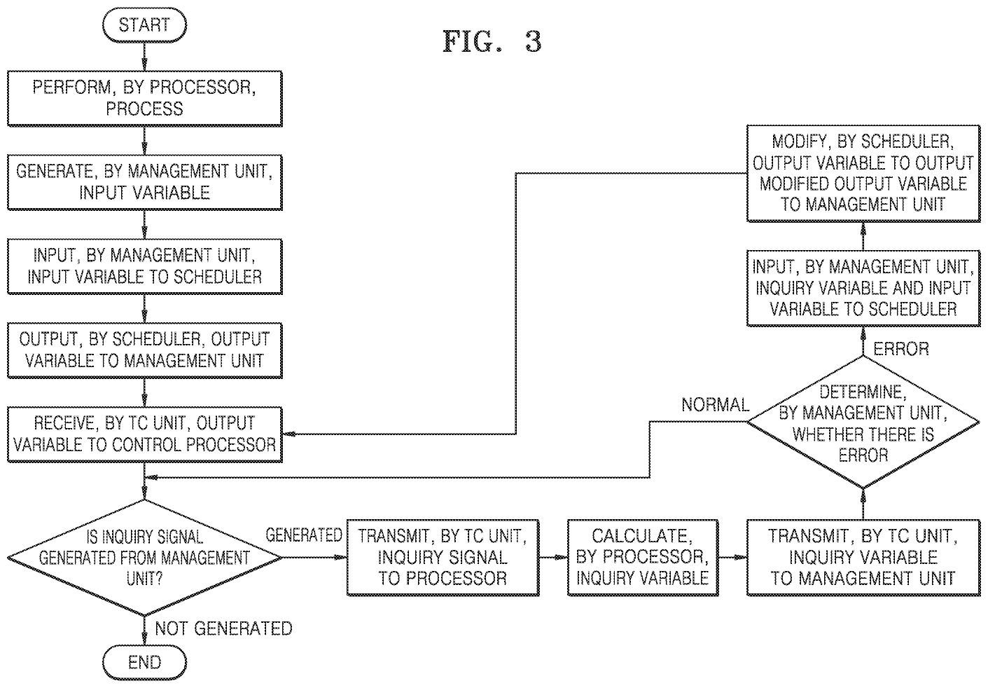

The controller 20 may control the processor 10. The controller 20 will be described later with reference to FIG. 3.

FIG. 3 is a schematic flowchart of a method of manufacturing a display device, according to an embodiment.

Referring to FIGS. 1 to 3, the display device manufacturing apparatus 1 may efficiently perform processes while actively saving electricity by considering the current process state.

Each of the plurality of process devices 111 may be in a power saving mode. For example, the plurality of first process devices 111-1, the plurality of second process devices 111-2, the plurality of third process devices 111-3, . . . , and the plurality of Nth process devices 111-N may be in a power saving mode.

That is, the plurality of process devices 111 may be switched between an operating mode, a power saving mode, and an off mode. In the operating mode, the plurality of process devices 111 may process the product GD. In the operating mode, the plurality of process devices 111 may continue to consume high power regardless of whether the process devices 111 are currently processing the product GD. In the power saving mode, the plurality of process devices 111 may not process the product GD, and the amount of power used may be reduced compared to the operating mode. In the off mode, the plurality of process devices 111 may be turned off. Accordingly, in the off mode, the plurality of process devices 111 may not process the product GD and may not consume power.

It may take preparation time for preheating or setting the plurality of process devices 111 to switch from the off mode or the power saving mode to the operating mode. In particular, it may take a considerable amount of time for the plurality of process devices 111 to switch from the off mode to the operating mode. On the other hand, the time for the plurality of process devices 111 to switch from the power saving mode to the operating mode may be short compared to the time for switching from the off mode to the operating mode.

The degree of power saving of the plurality of process devices 111 in the power saving mode may be adjusted to a plurality of levels. That is, in each of the plurality of first process devices 111-1, the plurality of second process devices 111-2, the plurality of third process devices 111-3, . . . , and the plurality of Nth process devices 111-N, the degree of power saving in the power saving mode may be adjusted to a plurality of levels. For example, the degree of power saving may be adjusted between level 1 and level 10, and as the level increases, the degree of power saving may increase.

In a power saving mode with a high degree of power saving, power usage may be lower compared to a case with a low degree of power saving. However, the time to switch from a power saving mode with a high degree of power saving to the operating mode may be longer than the time it takes to switch from a power saving mode with a low degree of power saving to the operating mode.

The controller 20 may control the processor 10 and may include a management unit 21, a scheduler 22, and a tool control (TC) unit 23.

The management unit 21 may generate an input variable IVL including information about the current process state and input the input variable IVL to the scheduler 22.

The input variable IVL may include the target number of products GD to be processed during a predefined time duration in each of the plurality of process lines 11, the number of process devices 111 arranged in each of the plurality of process lines 11, and the processing speed of each of the process devices 111 arranged in each of the plurality of process lines 11. The predefined time duration may be one day (24 hours). In that case, the input variable IVL may include the target number of products GD to be processed in each of the plurality of process lines 11 in 24 hours.

For example, the input variable IVL may include the target number of products GD to be processed during a predefined time in each of the first process line 11-1, the second process line 11-2, the third process line 11-3, . . . , and the Nth process line 11-N, the numbers of first process devices 111-1, second process devices 111-2, third process devices 111-3, . . . , and Nth process devices 111-N, and the processing speeds of the plurality of first process devices 111-1, the plurality of second process devices 111-2, the plurality of third process devices 111-3, . . . , and the plurality of Nth process devices 111-N.

Table 1 below is an example to explain the above-mentioned input variable IVL.

TABLE 1

| | 1st process | 2nd process | 3rd process | . . . | Nth process |
|---|---|---|---|---|---|
| | line 11-1 | line 11-2 | line 11-3 | | line 11-N |
| Target | 400 | 550 | 600 | . . . | 770 |
| number of | | | | | |
| products | | | | | |
| GD to be | | | | | |
| processed | | | | | |
| during a | | | | | |
| predefined | | | | | |
| period of | | | | | |
| time | | | | | |
| (per day) | | | | | |
| Number of | 10 | 7 | 12 | . . . | 15 |
| process | | | | | |
| devices | | | | | |
| 111 | | | | | |
| Processing | 120 | 300 | 160 | . . . | 170 |
| speed of | | | | | |
| process | | | | | |
| device 111 | | | | | |
| (Number | | | | | |
| of products | | | | | |
| GD that | | | | | |
| can be | | | | | |
| processed | | | | | |
| per day | | | | | |
| per | | | | | |
| process | | | | | |
| device | | | | | |
| 111) | | | | | |

The input variable IVL generated by the management unit 21 may include information that the target number of products GD to be processed by the first process line per day is 400, the number of first process devices 111-1 is 10, and the number of products GD, which can be processed per day by each of the plurality of first process devices 111-1, is 120.

The input variable IVL may include information that the target number of products GD to be processed by the second process line per day is 550, the number of second process devices 111-2 is 7, and the number of products GD, which can be processed per day by each of the plurality of second process devices 111-2, is 300.

The input variable IVL may include information that the target number of products GD to be processed by the third process line per day is 600, the number of third process devices 111-3 is 12, and the number of products GD, which can be processed per day by each of the plurality of third process devices 111-3, is 160.

In addition, the input variable IVL may include information that the target number of products GD to be processed by the Nth process line per day is 770, the number of Nth process devices 111-N is 15, and the number of products GD, which can be processed per day by each of the plurality of Nth process devices 111-N, is 170.

The scheduler 22 may receive information about the current process state from the management unit 21 and calculate power saving information, which is a condition for efficiently saving power of the processor 10 without interfering with the process of the processor 10. That is, the scheduler 22 may receive the input variable IVL from the management unit 21 and generate an output variable OVL including power saving information to the management unit 21.

In this case, the output variable OVL may include information about a power saving process device, which is subject to power saving mode from among the plurality of process devices 111, a power saving start time of the power saving process device, a power saving end time of the power saving process device, and a power saving degree of the power saving process device. The power saving end time may be determined by considering a preparation time for switching from the power saving mode to the operating mode.

For example, the output variable OVL may include information about a power saving process device that may be subjected to power saving mode, out of the plurality of first process devices 111-1, the plurality of second process devices 111-2, the plurality of third process devices 111-3, . . . , and the plurality of Nth process devices 111-N, a power saving start time of the power saving process device, and a power saving end time of the power saving process device.

Table 2 below is an example to explain the above-mentioned input variable IVL.

| | 1st process line 11-1 | 2nd process line 11-2 | |
|---|---|---|---|
| Power | 1st-1 process device | 2nd-1 process device 111-21 | |
| saving | 111-11 | 1) 09:20-10:50, Lev. 6 | |
| information | Non-power saving | 2) 15:10-18:00, Lev. 5 | |
| | 1st-2 process device | 3) 19:00-20:30, Lev. 4 | |
| | 111-12 | 2nd-2 process device 111-22 | |
| | 1) 12:00-12:30, Lev. 3 | Non-power saving | |
| | 2) 12:40-15:30, Lev. 5 | . | |
| | 3) 18:00-20:00, Lev. 2 | . | |
| | . | . | |
| | . | 2nd-N process device 111-2N | |
| | . | 1) 11:00-12:20, Lev. 5 | |
| | 1st-N process device | 2) 13:40-16:30, Lev. 7 | |
| | 111-1N | 3) 17:20-17:30, Lev. 3 | |
| | 1) 07:00-12:30, Lev. 3 | | |
| | 2) 15:00-21:00, Lev. 5 | | |
| | 3rd process line 11-3 | . . . | Nth process line 11-N |
| Power | 3rd-1 process device | . . . | Nth-1 process device |
| saving | 111-31 | | 111-N1 |
| information | 1) 07:20-12:50, Lev. 2 | | Non-power saving |
| | 2) 15:10-21:10 Lev. 4 | | Nth-2 process device |
| | 3rd-2 process device | | 111-N2 |
| | 111-32 | | 1) 12:20-12:50, Lev. 7 |
| | 1) 09:10-10:40, Lev. 2 | | 2) 13:30-15:20, Lev. 5 |
| | 2) 15:50-18:10, Lev. 3 | | 3) 18:10-20:10, Lev. 5 |
| | 3) 19:10-21:40, Lev. 2 | | . |
| | . | | . |
| | . | | . |
| | . | | Nth-N process device |
| | 3rd-N process device | | 111-NN |
| | 111-3N | | 1) 07:30-13:00, Lev. 6 |
| | Non-power saving | | 2) 15:30-21:20 Lev. 5 |

The plurality of process devices 111 may maintain the operating mode for all times other than those listed in Table 2.

The output variable OVL output by the scheduler 22 may include information that, in the first process line 11-1, the 1st-1 process device 111-11 is maintained in a non-power saving state (operating mode), the 1st-2 process device 111-12 is maintained in a level 3 power saving mode from 12:00 to 12:30, a level 5 power saving mode from 12:40 to 15:30, and a level 2 power saving mode from 18:00 to 20:00, and the 1st-N process device 111-1N is maintained in a level 3 power saving mode from 07:00 to 12:30 and a level 5 power saving mode from 15:00 to 21:00. That is, among the plurality of first process devices 111-1, the 1st-2 process device 111-12 and the 1st-N process device 111-1N may be power-saving process devices.

The output variable OVL may include information that, in the second process line 11-2, the 2nd-1 process device 111-21 is maintained in a level 6 power saving mode from 09:20 to 10:50, a level 5 power saving mode from 15:10 to 18:00, and a level 4 power saving mode from 19:00 to 20:30, the 2nd-2 process device 111-22 is maintained in a non-power saving state (operating mode), and the 2nd-N process device 111-2N is maintained in a level 5 power saving mode from 11:00 to 12:20, a level 7 power saving mode from 13:40 to 16:30, and a level 5 power saving mode from 17:20 to 17:30. That is, among the plurality of second process devices 111-2, the 2nd-1 process device 111-22 and the 2nd-N process device 111-2N may be power saving process devices.

The output variable OVL may include information that, in the third process line 11-3, the 3rd-1 process device 111-31 is maintained in a level 2 power saving mode from 07:20 to 12:50 and a level 4 power saving mode from 15:10 to 21:10, the 3rd-2 process device 111-32 is maintained in a level 2 power saving mode from 09:10 to 10:40, a level 3 power saving mode from 15:50 to 18:10, and a level 2 power saving mode from 19:10 to 21:40, and the 3rd-N process device 111-3N is maintained in a non-power saving state (operating mode). That is, among the plurality of third process devices 111-3, the 3rd-1 process device 111-31 and the 3rd-2 process device 111-32 may be power saving process devices.

In addition, the output variable OVL may include information that, in the Nth process line 11-N, the Nth-1 process device 111-N1 is maintained in a non-power-saving state (operating mode), the Nth-2 process device 111-N2 is maintained in a level 7 power saving mode from 12:20 to 12:50, a level 5 power saving mode from 13:30 to 15:20, and a level 5 power saving mode from 18:10 to 20:10, and the Nth-N process device 111-NN is maintained in a level 6 power saving mode from 07:30 to 13:00 and a level 5 power saving mode from 15:30 to 21:20. That is, among the plurality of Nth process devices 111-1, the Nth-2 process device 111-N2 and the Nth-N process device 111-NN may be power-saving process devices.

The TC unit 23 may receive the output variable OVL from the management unit 21 and control the processor 10 according to the output variable OVL. Accordingly, the processor 10 may operate according to the power saving status, power saving time, and power saving degree of each of the plurality of process devices 111, which are included in the output variable OVL.

The management unit 21 may generate an inquiry signal to inquire the current power saving state of the processor 10. The inquiry signal may be generated to check whether the current process is being performed without error even though at least one of the plurality of process devices 111 is in a power saving mode. Alternatively, the inquiry signal may be generated to correct the output variable OVL when the manufacturing plan of the display device manufacturing apparatus 1 changes. For example, the inquiry signal may be generated when the target number of products GD to be processed in one day by the first process line 11-1 changes from 400 to 600.

The management unit 21 may generate an inquiry signal multiple times at regular time intervals. For example, the management unit 21 may generate an inquiry signal multiple times at intervals of 1 hour, or the management unit 21 may generate an inquiry signal 1 hour after the power saving start time and 1 hour before the power saving end time.

The TC unit 23 may transmit the inquiry signal generated by the management unit 21 to the processor 10. Accordingly, the inquiry signal may be input from the management unit 21 to the processor 10.

When the processor 10 receives the inquiry signal, the processor 10 may determine (e.g., retrieve, calculate) an inquiry variable indicating the current status of the processor 10. The inquiry variable may include the number of products GD processed to date in each of the plurality of process lines 11.

For example, the inquiry variable may include the number of products GD processed to date in the first process line 11-1, the number of products GD processed to date in the second process line 11-2, the number of products GD processed to date in the third process line 11-3, . . . , and the number of products GD processed to date in the Nth process line 11-N.

Afterwards, the TC unit 23 may transmit the inquiry variable to the management unit 21. Accordingly, the inquiry variable may be input from the TC unit 23 to the management unit 21. The management unit 21 may determine whether there is an error in the operation of the processor 10 by comparing the inquiry variable, the input variable IVL, and the output variable OVL.

The management unit 21 may compare the ideal number of products GD that should have been processed to date in each of the plurality of process lines 11, the ideal number being calculated from the input variable IVL and the output variable OVL, to the actual number of products GD processed to date in each of the plurality of process lines 11, the actual number being included in the inquiry variable. In addition, when the difference between the ideal number and the actual number is greater than a predefined value, the management unit 21 may determine that there is an error in the operation of the processor 10, and when the difference is less than or equal to the predefined value, the management unit 21 may determine that the operation of the process unit 10 is normal.

When the management unit 21 determines that the operation of the processor 10 is normal, the procedure may be terminated as long as there is no additional inquiry signal from the management unit 21.

When the management unit 21 determines that the operation of the processor 10 has an error, the management unit 21 may input the inquiry variable and the input variable IVL to the scheduler 22. The scheduler 22 may receive the inquiry variable and the input variable IVL, modify the output variable OVL, and output the modified output variable to the management unit 21. The TC unit 23 may receive the modified output variable OVL from the management unit 21 and control the processor 10 according to the modified output variable OVL.

The management unit 21 may calculate the amount of power saved compared to the case where all of the plurality of process devices 111 are in an operating state. For example, the management unit 21 may calculate the amount of power saved for each of the plurality of process lines 11. In addition, the management unit 21 may calculate the amount of power saved for each of the plurality of process devices 111. The management unit 21 may calculate the amount of power saved daily, weekly, monthly, or annually. The management unit 21 may communicate with a user device US. The management unit 21 may transmit the saved amount of power to the user device US. For example, the management unit 21 may plot the amount of power saved in a graph and transmit the plotted amount of power to the user device US.

According to an embodiment, unnecessary consumption of power and rapid depreciation of various expensive components, which occur when the plurality of process devices 111 are always set to the operating mode, may be reduced.

In addition, according to an embodiment, process inefficiencies, which occur due to significant preparation time required while one or more of the plurality of process devices 111 are switched from the off mode to the operating mode, may be reduced.

That is, in an embodiment, by flexibly changing the power saving degree of each of the plurality of process devices 111 by considering the current process state, process efficiency may be improved, and unnecessary power consumption and depreciation of various components may be reduced, thereby reducing the manufacturing cost of the display device.

FIG. 4 is a schematic block diagram of a heat treatment device 12 according to an embodiment.

Referring to FIGS. 1 to 4, the heat treatment device 12 may be a device that performs heat treatment on the product GD. The heat treatment device 12 may be a deposition device for depositing a deposition material on the product GD.

At least one of the plurality of process lines 11 may include the heat treatment device 12. At least one of the plurality of first process devices 111-1, the plurality of second process devices 111-2, the plurality of third process devices 111-3, . . . , and the plurality of Nth process devices 111-N may include the heat treatment device 12.

For example, when the first process line 11-1 includes the heat treatment device 12, the first process may include a heat treatment process in which a product is heat treated. In this case, the first product GD1 may be heat treated to form the second product GD2 by the first process of the first process device 111-1.

The heat treatment device 12 may include a chamber 121, a heater 122, a temperature sensor 123, and a temperature controller 124. The chamber 121 may provide an internal space to store a product while heat treatment processing for the product is in progress. The heater 122 may be disposed inside the chamber 121 to emit heat. The internal space of the chamber 121 may be heated by the heater 122. The temperature sensor 123 may be disposed inside the chamber 121 and may detect the temperature inside the chamber 121. The temperature controller 124 may control the degree to which the heater 122 emits heat based on information detected by the temperature sensor 123.

The temperature controller 124 may be controlled by the TC unit 23. The TC unit 23 may adjust the degree of power saving by controlling the temperature controller 124. That is, the TC unit 23 may control the temperature controller 124 so that the amount of heat generated by the heater 122 is low when the power saving degree of the process device 111 received from the management unit 21 is high, and may control the temperature controller 124 so that the amount of heat generated by the heater 122 is high when the power saving degree of the process device 111 received from the management unit 21 is low.

FIG. 5 is a schematic block diagram of a laser process device 13 according to an embodiment.

Referring to FIGS. 1 to 3 and 5, the laser process device 13 may be a device that performs laser processing on the product GD. The laser process device 13 may be an exposure device that performs an extreme ultraviolet (EUV) process or a laser device that performs an excimer laser annealing (ELA) process.

At least one of the plurality of process lines 11 may include the laser process device 13. At least one of the plurality of first process devices 111-1, the plurality of second process devices 111-2, the plurality of third process devices 111-3, . . . , and the plurality of Nth process devices 111-N may include the laser process device 13.

For example, when the second process line 11-2 includes the laser process device 13, the second process may include a laser processing process that performs laser processing on a product. In this case, the second product GD2 may be laser-processed into the third product GD3 by the second process of the second process device 111-2.

The laser process device 13 may include a laser irradiation unit 131, a power sensor 132, and a power controller 133.

The laser irradiation unit 131 may irradiate laser. The product GD may be processed by a laser irradiated from the laser irradiation unit 131. The power sensor 132 may detect the power of the laser. The power controller 133 may control the power level of the laser irradiated by the laser irradiation unit 131 based on information detected by the power sensor 132.

The power controller 133 may be controlled by the TC unit 23. The TC unit 23 may adjust the degree of power saving by controlling the power controller 133. That is, the TC unit 23 may control the power controller 133 so that the power of the laser irradiated by the laser irradiation unit 131 is low in response to the power saving degree of the process device 111 received from the management unit 21 being set on high, and may control the power controller 133 so that the power of the laser irradiated by the laser irradiation unit 131 is high in response to the power saving degree of the process device 111 received from the management unit 21 being set on low.

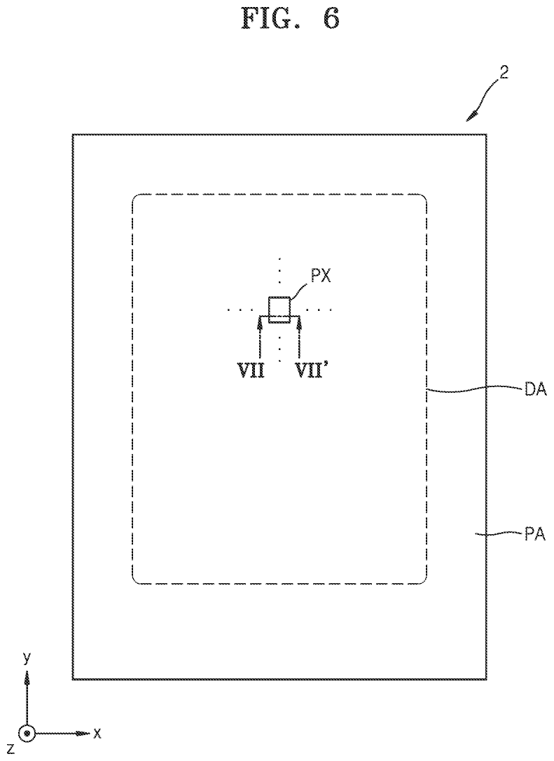

FIG. 6 is a plan view schematically illustrating a display device according to an embodiment.

Referring to FIG. 6, a display device 2 manufactured according to an embodiment may include a display area DA and a peripheral area PA located on an outer side of the display area DA. The display device 2 may provide an image by an array of a plurality of pixels PX arranged two-dimensionally in the display area DA.

The peripheral area PA is an area that does not provide an image, and may completely or partially surround the display area DA. The peripheral area PA may include components such as drivers for providing electrical signals or power to the pixel circuits corresponding to each of the pixels PX. The peripheral area PA may include pads, which are areas to which electronic devices, printed circuit boards, etc. may be electrically connected.

Hereinafter, the display device 2 will be described as including an organic light-emitting diode OLED as a light-emitting element, but the display device 2 of the disclosure is not limited thereto. In another embodiment, the display device 2 may be a light-emitting display device including inorganic light-emitting diodes, such as an inorganic light-emitting display. The inorganic light-emitting diodes may include PN diodes including an inorganic semiconductor-based material. When a voltage is applied to the PN junction diode in the forward direction, holes and electrons are injected, and the energy generated by the recombination of the holes and electrons is converted into light energy to emit light of a certain color. The inorganic light-emitting diodes described above may have a width of about 1 to about 1000 micrometers, and in some embodiments, the inorganic light-emitting diodes may be referred to as micro-LEDs. As another embodiment, the display device 2 may be a quantum dot light-emitting display.

The display device 2 may be used as a display screen for a variety of products, including portable electronic devices such as mobile phones, smart phones, tablet personal computers, mobile communication terminals, electronic notebooks, e-books, portable multimedia players (PMPs), navigation devices, and ultra-mobile PCs (UMPCs), etc., as well as televisions, laptops, monitors, billboards, internet of things (IoT) devices, etc. In addition, the display device 2 according to an embodiment may be used in a wearable device, such as a smart watch, a watch phone, an eyewear-type display, and a head-mounted display (HMD). In addition, the display device 2 according to an embodiment may be used in an instrument panel of an automobile, and as a center information display (CID) arranged on the center fascia or dashboard of an automobile, as a room mirror display in place of a side mirror of an automobile, as entertainment for the back seat of an automobile, and as a display screen arranged on the back of a front seat.

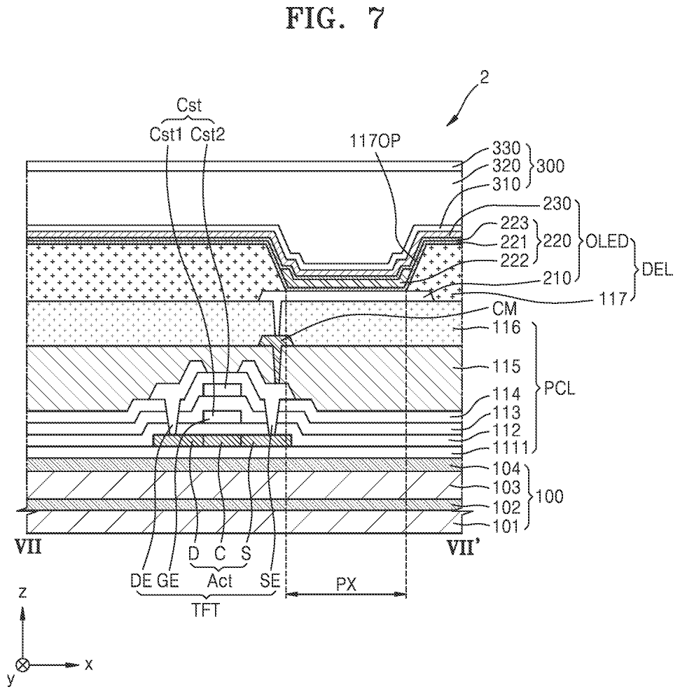

FIG. 7 is a cross-sectional view schematically illustrating a display device according to an embodiment, which may correspond to a cross-section of the display device taken along line VII-VII′ in FIG. 6.

Referring to FIG. 7, the display device 2 may include a stacked structure of a substrate 100, a pixel circuit layer PCL, a display element layer DEL, and an encapsulation layer 300.

The substrate 100 may be a multi-layer structure including a base layer, which includes a polymeric resin, and an inorganic layer. For example, the substrate 100 may include a base layer, which includes a polymeric resin, and a barrier layer of an inorganic insulation layer. For example, the substrate 100 may include a first base layer 101, a first barrier layer 102, a second base layer 103, and a second barrier layer 104, which are stacked sequentially. The first base layer 101 and the second base layer 103 may include polyimide (PI), polyethersulfone (PES), polyarylate, polyetherimide (PEI), polyethyelenene napthalate (PEN), polyethylene terephthalate (PET), polyphenylene sulfide (PPS), polycarbonate, cellulose triacetate (TAC), and/or cellulose acetate propionate (CAP), or the like. The first barrier layer 102 and the second barrier layer 104 may include an inorganic insulation material, such as silicon oxide, silicon oxynitride, and/or silicon nitride. The substrate 100 may be flexible.

A pixel circuit layer PCL is disposed on the substrate 100. FIG. 7 illustrates that the pixel circuit layer PCL includes a thin-film transistor TFT, a buffer layer 1111, a first gate insulation layer 112, a second gate insulation layer 113, an interlayer insulation layer 114, a first planarized insulation layer 115, and a second planarized insulation layer 116, disposed below and/or above components of the thin-film transistor TFT.

The buffer layer 1111 may reduce or block the infiltration of debris, moisture, or foreign air from a lower portion of the substrate 100, and may provide a flat surface on the substrate 100. The buffer layer 1111 may include an inorganic insulation material such as silicon oxide, silicon oxynitride, or silicon nitride, and may be a single-layer or multi-layer structure including any of the aforementioned materials.

The thin-film transistor TFT on the buffer layer 1111 includes a semiconductor layer Act, and the semiconductor layer Act may include poly-silicon (poly-Si). Alternatively, the semiconductor layer Act may include amorphous silicon (a-Si), may include an oxide semiconductor, and may include an organic semiconductor or the like. The semiconductor layer Act may include a channel area C and, arranged on each side of the channel area C, a drain area D and a source area S. A gate electrode GE may overlap the channel area C.

The gate electrode GE may include a low-resistance metal material. The gate electrode GE may include a conductive material including molybdenum (Mo), aluminum (AI), copper (Cu), titanium (Ti), etc., and may be formed as a multi-layer or a single layer including the above materials.

The first gate insulation layer 112 between the semiconductor layer Act and the gate electrode GE may include an inorganic insulation material such as silicon oxide (SiO₂), silicon nitride (SiNₓ), silicon oxide (SiON), aluminum oxide (Al₂O₃), titanium oxide (TiO₂), tantalum oxide (Ta₂O₅), hafnium oxide (HfO₂), or zinc oxide (ZnOₓ) or the like. The zinc oxide (ZnOₓ) may be zinc oxide (ZnO) and/or zinc peroxide (ZnO₂).

The second gate insulation layer 113 may be provided to cover the gate electrode GE. The second gate insulation layer 113 may include an inorganic insulation material such as silicon oxide (SiO₂), silicon nitride (SiNₓ), silicon oxide (SiON), aluminum oxide (Al₂O₃), titanium oxide (TiO₂), tantalum oxide (Ta₂O₅), hafnium oxide (HfO₂), or zinc oxide (ZnOₓ) or the like, similar to the first gate insulation layer 112. The zinc oxide (ZnOₓ) may be zinc oxide (ZnO) and/or zinc peroxide (ZnO₂).

On top of the second gate insulation layer 113, an upper electrode Cst2 of the storage capacitor Cst may be disposed. The upper electrode Cst2 may overlap the gate electrode GE below the upper electrode Cst2. In this case, the gate electrode GE and the upper electrode Cst2, which overlap the second gate insulation layer 113 located therebetween, may form a storage capacitor Cst. That is, the gate electrode GE may function as a lower electrode Cst1 of the storage capacitor Cst.

As such, the storage capacitor Cst and the thin-film transistor TFT may be positioned to overlap each other. In some embodiments, the storage capacitor Cst may be formed to not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multi-layer of the aforementioned materials.

The interlayer insulation layer 114 may cover the upper electrode Cst2. The interlayer insulation layer 114 may include silicon oxide (SiO₂), silicon nitride (SiNₓ), silicon oxide (SiON), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may be zinc oxide (ZnO) and/or zinc peroxide (ZnO₂). The interlayer insulation layer 114 may be a single layer or a multi-layer, including the inorganic insulation material described above.

The drain electrode DE and the source electrode SE may each be located on the interlayer insulation layer 114. The drain electrode DE and the source electrode SE may be connected to the drain area D and the source area S, respectively, through contact holes formed in insulation layers beneath the drain electrode DE and the source electrode SE. The drain electrode DE and the source electrode SE may include a material with good conductivity. The drain electrode DE and the source electrode SE may include a conductive material including molybdenum (Mo), aluminum (AI), copper (Cu), titanium (Ti), etc., and may be formed as a multi-layer or a single layer, including the above materials. In an embodiment, the drain electrode DE and the source electrode SE may have a multi-layer structure of Ti/Al/Ti.

The first planarized insulation layer 115 may cover the drain electrode DE and the source electrode SE. The first planarized insulation layer 115 may include organic insulation materials such as general-purpose polymers such as polymethylmethacrylate (PMMA) or polystyrene (PS), polymer derivatives that have a phenolic group, acrylic-based polymers, imide-based polymers, aryl ether-based polymers, amide-based polymers, fluorinated polymers, p-xylene-based polymers, vinyl alcohol-based polymers, and blends thereof.

The second planarized insulation layer 116 may be disposed on the first planarized insulation layer 115. The second planarized insulation layer 116 may include the same materials as the first planarized insulation layer 115, and may include organic insulation materials such as general-purpose polymers such as polymethylmethacrylate (PMMA) or polystyrene (PS), polymer derivatives that have a phenolic group, acrylic-based polymers, imide-based polymers, aryl ether-based polymers, amide-based polymers, fluorinated polymers, p-xylene-based polymers, vinyl alcohol-based polymers, and blends thereof.

A display element layer DEL may be arranged on the pixel circuit layer PCL having the structure described above. The display element layer DEL may include an organic light-emitting diode OLED as a display element (in other words, a light-emitting element), and the organic light-emitting diode OLED may include a stacked structure of a pixel electrode 210, an intermediate layer 220, and a common electrode 230. The organic light-emitting diode OLED, for example, may emit red, green, or blue light or may emit red, green, blue, or white light. The organic light-emitting diode OLED emits light through a light-emitting area, and the light-emitting area may be defined as a pixel PX.

The pixel electrode 210 of the organic light-emitting diode OLED may be electrically connected to the thin-film transistor TFT through contact holes formed in the second planarized insulation layer 116 and the first planarized insulation layer 115 and a contact metal CM disposed on the first planarized insulation layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective film including silver (Ag), magnesium (Mg), aluminum (AI), platinum (Pt), palladium (Pd), gold (Au), nickel (Ni), neodymium (Nd), iridium (Ir), chromium (Cr), or compounds thereof. In another embodiment, the pixel electrode 210 may further include a film formed of ITO, IZO, ZnO, or In₂O₃, above/below the reflective film described above.

Disposed on the pixel electrode 210 is a bank layer 117 that has an opening 117OP exposing a central portion of the pixel electrode 210. The bank layer 117 may include an organic insulation material and/or an inorganic insulation material. The opening 117OP may define a light-emitting area for light emitted by the organic light-emitting diode OLED. For example, the size/width of the opening 117OP may correspond to the size/width of the light-emitting area. Therefore, the size and/or width of the pixel PX may depend on the size and/or width of the opening 117OP of the corresponding bank layer 117.

The intermediate layer 220 may include an emission layer 222 formed to correspond to the pixel electrode 210. The emission layer 222 may include a polymeric or low-molecular-weight organic material that emits a certain color of light. Alternatively, the emission layer 222 may include an inorganic light-emitting material, or may include quantum dots.

In an embodiment, the intermediate layer 220 may include a first functional layer 221 and a second functional layer 223, arranged below and above the emission layer 222, respectively. The first functional layer 221 may include, for example, a hole transport layer (HTL), or may include a hole transport layer and a hole injection layer (HIL). The second functional layer 223 is a component disposed above the emission layer 222 and may include an electron transport layer (ETL) and/or an electron injection layer (EIL). The first functional layer 221 and/or the second functional layer 223 may be a common layer formed to cover the entire substrate 100, as is the common electrode 230, which will be described below.

The common electrode 230 is disposed on the pixel electrode 210 and may overlap the pixel electrode 210. The common electrode 230 may be made of a low-work-function conductive material. For example, the common electrode 230 may include a (semi-) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), an alloy thereof, or the like. Alternatively, the common electrode 230 may further include a layer such as ITO, IZO, ZnO, or In₂O₃ on the (semi-) transparent layer including the materials described above. The common electrode 230 may be integrally formed to cover the entire substrate 100.

The encapsulation layer 300 may be disposed on the display element layer DEL and cover the display element layer DEL. The encapsulation layer 300 includes at least one inorganic encapsulation layer and at least one organic encapsulation layer, and as an example, FIG. 7 illustrates that the encapsulation layer 300 includes a first inorganic encapsulation layer 310, an organic encapsulation layer 320, and a second inorganic encapsulation layer 330, which are stacked sequentially.

The first inorganic encapsulation layer 310 and the second inorganic encapsulation layer 330 may include one or more inorganic materials selected from aluminum oxide, titanium oxide, tantalum oxide, hafnium oxide, zinc oxide, silicon oxide, silicon nitride, and silicon oxynitride. The organic encapsulation layer 320 may include a material of the polymer family. Polymer-based materials may include acrylic-based resins, epoxy-based resins, polyimides, polyethylene, etc. In an embodiment, the organic encapsulation layer 320 may include acrylate. In an embodiment, the organic encapsulation layer 320 may include acrylate. The organic encapsulation layer 320 may be formed by curing a monomer, or by applying a polymer. The organic encapsulation layer 320 may be transparent.

Although not shown, a touch sensor layer may be arranged on the encapsulation layer 300, and an optical functional layer may be arranged on the touch sensor layer. The touch sensor layer may obtain coordinate information according to an external input, for example, a touch event. The optical functional layer may reduce reflectance of light (external light) incident toward the display device from the outside and/or improve color purity of light emitted from the display device. In an embodiment, the optical functional layer may include a retarder and/or a polarizer. The retarder may be of a film type or a liquid crystal coating type, and may include a λ/2 retarder and/or a λ/4 retarder. The polarizer may also be of a film type or a liquid crystal coating type. The film type may include a stretchable synthetic resin film, and the liquid crystal coating type may include liquid crystals arranged in a certain arrangement. The retarder and the polarizer may further include a protective film.

An adhesive member may be arranged between the touch electrode layer and the optical functional layer. As the adhesive member, general adhesive members known in the art may be employed without limitation. The adhesive member may be a pressure-sensitive adhesive (PSA).

The product GD (see FIG. 2) described with reference to FIGS. 1 to 5 may include the display device 2. For example, the product GD (see FIG. 2) described with reference to FIGS. 1 to 5 may include the substrate 100.

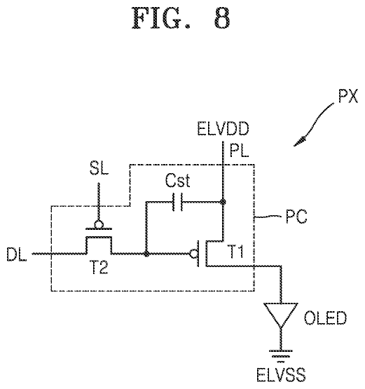

FIG. 8 is an equivalent circuit diagram of any pixel of a display panel according to an embodiment.

Each pixel PX may include a pixel circuit PC, and a display element connected to the pixel circuit PC, such as an organic light-emitting diode OLED. The pixel circuit PC may include a first thin-film transistor T1, a second thin-film transistor T2, and a storage capacitor Cst. Each pixel PX may emit light, such as red, green, blue or white light, via an organic light-emitting diode OLED.

The second thin-film transistor T2 is a switching thin-film transistor, connected to a scan line SL and a data line DL, and data voltage input from the data line DL may be transferred to the first thin-film transistor T1, based on a switching voltage input from the scan line SL. The storage capacitor Cst is connected to the second thin-film transistor T2 and a driving voltage line PL, and may store a voltage corresponding to the difference between a voltage received from the second thin-film transistor T2 and a first power supply voltage ELVDD supplied to the driving voltage line PL.

The first thin-film transistor T1 is a driving thin-film transistor, which is connected to the driving voltage line PL and the storage capacitor Cst, and may control a drive current flowing from the driving voltage line PL to the organic light-emitting diode OLED in response to a voltage value stored in the storage capacitor Cst. The organic light-emitting diode OLED may emit light that has a certain luminance due to the drive current. A counter electrode (for example, cathode) of the organic light-emitting diode OLED may be supplied with a second power supply voltage ELVSS.

FIG. 8 illustrates a pixel circuit PC including two thin-film transistors and one storage capacitor, but the disclosure is not limited thereto. The number of thin-film transistors and the number of storage capacitors may be variously changed according to the design of the pixel circuit PC. For example, the pixel circuit PC may further include four, five or more thin-film transistors in addition to the two thin-film transistors described above.

According to embodiments of the disclosure, the manufacturing cost required to manufacture a display device may be reduced by using the display device manufacturing apparatus.

The effects of the disclosure are not limited to the effects mentioned above, and other effects not mentioned will be clearly understood by those skilled in the art from the description of the claims.

It should be understood that embodiments described herein should be considered in a descriptive sense only and not for purposes of limiting the scope of the disclosure. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display device, the apparatus comprising:
a processor including a first process line including a plurality of first process devices configured to perform a first process, and a second process line including a plurality of second process devices configured to perform a second process; and
a controller configured to control the processor,
wherein each of the plurality of first process devices and the plurality of second process devices is configured to operate in a power saving mode, and
the controller includes:
a management unit configured to generate an input variable including a target number of products to be processed during a predefined time duration in the first process line, a target number of products to be processed during the predefined time duration in the second process line, a number of the plurality of first process devices, a number of the plurality of second process devices, a processing speed of the plurality of first process devices, and a processing speed of the plurality of second process devices;
a scheduler configured to receive the input variable from the management unit and output an output variable to the management unit; and
a tool control (TC) unit configured to receive the output variable from the management unit and control the processor according to the output variable,
wherein the output variable includes information about a power saving process device operating in a power saving mode among the plurality of first process devices and the plurality of second process devices, a power saving start time of the power saving process device, and a power saving end time of the power saving process device.

2. The apparatus of claim 1, wherein, in each of the plurality of first process devices and the plurality of second process devices, a degree of power saving in the power saving mode is adjusted to a plurality of levels, and the output variable further includes a degree of power saving of the power saving process device.

3. The apparatus of claim 2, wherein at least one of the plurality of first process devices and the plurality of second process devices includes a heat treatment device configured to heat-treat the products,
wherein the heat treatment device includes:
a chamber;
a heater disposed inside the chamber to emit heat;
a temperature sensor configured to detect a temperature inside the chamber; and
a temperature controller configured to control a degree to which the heater emits heat based on information detected by the temperature sensor,
wherein the TC unit is further configured to adjust the degree of power saving by controlling the temperature controller.

4. The apparatus of claim 2, wherein at least one of the plurality of first process devices and the plurality of second process devices includes a laser process device,
wherein the laser process device includes:
a laser irradiation unit configured to irradiate a laser;
a power sensor configured to detect power of the laser; and
a power controller configured to control a degree of the power of the laser irradiated by the laser irradiation unit based on the information detected by the power sensor,
wherein the TC unit is further configured to adjust the degree of power saving by controlling the power controller.

5. The apparatus of claim 1, wherein the management unit is further configured to generate an inquiry signal about a current power saving state of the processor.

6. The apparatus of claim 5, wherein the TC unit is further configured to transmit the inquiry signal to the processor,
the processor is further configured to determine, upon receiving the inquiry signal, an inquiry variable including a number of products processed to date in the first process line and a number of products processed to date in the second process line,
the TC unit is further configured to transmit the inquiry variable to the management unit, and
the management unit is further configured to compare the inquiry variable, the input variable, and the output variable with each other to determine whether there is an error in an operation of the processor.

7. The apparatus of claim 6, wherein, when the management unit is further configured to determine that an error occurred in the operation of the processor,
the management unit is further configured to input the inquiry variable and the input variable to the scheduler, and
the scheduler is further configured to receive the inquiry variable and the input variable, modify the output variable, and output the modified output variable to the management unit.

8. The apparatus of claim 7, wherein the TC unit is further configured to receive the modified output variable from the management unit and control the processor according to the modified output variable.

9. The apparatus of claim 5, wherein the management unit is further configured to generate the inquiry signal multiple times at regular time intervals.

10. The apparatus of claim 1, wherein the plurality of second process devices are each configured to perform the second process on the product on which the first process has been performed, and the first process is different from the second process.

11. A method of manufacturing a display device, the method comprising:
performing, by a processor, a process, the processor including a first process line including a plurality of first process devices configured to perform a first process and a second process line including a plurality of second process devices configured to perform a second process;
generating, by a management unit, an input variable including a target number of products to be processed during a predefined time duration in the first process line, a target number of products to be processed during the predefined time duration in the second process line, a number of the plurality of first process devices, a number of the plurality of second process devices, a processing speed of the plurality of first process devices, and a processing speed of the plurality of second process devices;
receiving, by a tool control (TC) unit, an output variable from the management unit to control the processor according to the output variable,
wherein the output variable includes information about a power saving process device operating in a power saving mode from among the plurality of first process devices and the plurality of second process devices, a power saving start time of the power saving process device, and a power saving end time of the power saving process device.

12. The method of claim 11, further comprising, in each of the plurality of first process devices and the plurality of second process devices, adjusting a degree of power saving in the power saving mode i to a selected level of a plurality of levels, and including a degree of power saving of the power saving process device in the output variable.

13. The method of claim 12, further comprising heat treating the products with a heat treatment device in at least one of the plurality of first process devices and the plurality of second process devices,
wherein the heat treating includes:
placing the products in a chamber;
applying heat with a heater disposed inside the chamber;
detecting a temperature inside the chamber;
controlling a degree to which the heater emits heat based on a temperature inside the chamber, and
adjusting the degree of power saving by controlling the temperature.

14. The method of claim 12, further comprising laser treating the products with a laser process device in at least one of the plurality of first process devices and the plurality of second process devices,
wherein the laser treating includes:
irradiating the products with a laser beam;
detecting a power level of the laser;
controlling a power level of the laser based on the power that is detected, and
adjusting the degree of power saving by controlling the power level.

15. The method of claim 11, further comprising generating, by the management unit, an inquiry signal about a current power saving state of the processor.

16. The method of claim 15, further comprising:
determining, by the processor upon receiving the inquiry signal, an inquiry variable including a number of products processed to date in the first process line and a number of products processed to date in the second process line;
transmitting, by the TC unit, the inquiry variable to the management unit; and
comparing, by the management unit, the inquiry variable, the input variable, and the output variable with each other to determine whether an error occurred in an operation of the processor.

17. The method of claim 16, further comprising:
upon determining that an error occurred in the operation of the processor,
using the inquiry variable and the input variable to modify the output variable and generate a modified output variable.

18. The method of claim 17, further comprising controlling the processor according to the modified output variable.

19. The method of claim 15, further comprising generating the inquiry signal multiple times at regular time intervals.

20. The method of claim 11, further comprising performing, via the plurality of second process devices, the second process on the product on which the first process has been performed, wherein the first process is different from the second process.
